(19) United States
(12) Patent Application Publication
(10) Pub. No.: US 2018/0031931 A1
(43) Pub. Date: Feb. 1, 2018

(54) ARRAY SUBSTRATE, METHOD OF MANUFACTURING THE ARRAY SUBSTRATE AND LIQUID CRYSTAL DISPLAY PANEL

(71) Applicant: Wuhan China Star Optoelectronics Technology Co Ltd., Wuhan, Hubei (CN)

(72) Inventor: Fang QIN, Shenzhen, Guangdong (CN)

(73) Assignee: Wuhan China Star Optoelectronics Technology Co., Ltd., Wuhan, Hubei (CN)

(21) Appl. No.: 15/126,381

(22) PCT Filed: Jul. 14, 2016
(86) PCT No.: PCT/CN2016/089999

§ 371 Date: Sep. 15, 2016

(30) Foreign Application Priority Data
Jun. 17, 2016 (CN) 201610431928.4

(51) Int. Cl. G02F 1/1362; H01L 27/12; G02F 1/1343

(52) U.S. Cl. CPC G02F 1/136213; G02F 1/134309; G02F 1/136227; H01L 27/1248; H01L 27/1262; G02F 2001/133357

(57) ABSTRACT

The present application discloses an array substrate, a method of manufacturing an array substrate, and a liquid crystal display panel. The array substrate includes a substrate; a channel layer; a first insulating layer; a gate electrode; a second insulating layer have a first through hole and a second through hole; a source electrode electrically connected to the channel layer through the first through hole; a drain electrode electrically connected to the channel layer through the second through hole; a planarization layer has a third through hole; a common electrode; a passivation layer has HfO₂ and a fourth through hole communication with the third through hole; and a pixel electrode electrically connected to the drain electrode through the third through hole and the fourth through hole, and the pixel electrode is disposed corresponding to the common electrode, the pixel electrode, the passivation layer and the common electrode constitute a storage capacitor.

### CROSS REFERENCE

This application claims the priority of Chinese Patent Application No. 201610431928.4, entitled “ARRAY SUBSTRATE, METHOD OF MANUFACTURING THE ARRAY SUBSTRATE AND LIQUID CRYSTAL DISPLAY PANEL”, filed on Jun. 17, 2016, the disclosure of which is incorporated herein by reference in its entirety.

### Field of the Invention

The present application relates to a display technology field, and more particularly to an array substrate, a method of manufacturing the array substrate and a liquid crystal display panel.

### Background of the Invention

A display device, such as a liquid crystal display, LCD is a commonly used electronic equipment, because of its low power consumption, small size, less weight and other characteristics, earning user's favor. The liquid crystal display typically includes an array substrate, a color filter substrate and a liquid crystal layer. The array substrate disposed opposite and spaced to the color filter substrate, the liquid crystal layer is interposed between the array substrate and the color filter substrate. The array substrate includes a thin film transistor distributed in array type, each of the thin film transistors are connected to a storage capacitor. In the conventional technology, since the dielectric layer of the storage capacitor is usually made of SiOx, therefore, the dielectric layer is usually small, leading to a smaller capacitance value of the storage capacitor.

### SUMMARY OF THE INVENTION

The present application provides an array substrate including:

a substrate,

a channel layer disposed adjacent to the surface of the substrate;

a first insulating layer covered the channel layer;

a gate electrode disposed on the surface of the first insulating layer remote from the channel layer;

a second insulating layer covered the gate electrode and a first through hole and a second through hole are disposed spaced apart in the second insulating layer;

a source electrode disposed on the second insulating layer, and the source electrode electrically connected to the channel layer through the first through hole;

a drain electrode disposed on the second insulating layer, and the drain electrode is electrically connected to the channel layer through the second through hole;

a planarization layer covered the source electrode and the drain electrode, and a third through hole disposed in the planarization layer corresponding to the drain electrode;

a common electrode disposed on the planarization layer;

a passivation layer covered the common electrode, and the passivation layer including HfO₂, a fourth through hole disposed in the passivation layer corresponding to the drain electrode, and the fourth through hole is communication with the third through hole; and

a pixel electrode disposed on the passivation layer, the pixel electrode is electrically connected to the drain electrode through the third through hole and the fourth through hole, and the pixel electrode is disposed corresponding to the common electrode, the pixel electrode, the passivation layer and the common electrode constitute a storage capacitor.

Wherein the array substrate further including:

a buffer layer disposed on the substrate; and

the channel layer is disposed on the surface of the buffer layer remote from the substrate.

Wherein the array substrate further including:

a first contact portion and a second contact portion, wherein the first contact portion and the second contact portion are in contact with the channel layer respectively, and the first contact portion and the second contact portion are disposed spaced apart;

the source electrode is connected to the first contact portion through the first through hole, the first contact portion is used to reduce the contact resistance between the source electrode and the channel layer; and

the drain electrode is connected to the second contact portion through the second through hole, the second contact portion is used to reduce the contact resistance between the drain electrode and the channel layer.

wherein the channel layer including a first end face and a second end face disposed opposite to each other, the first end face and the second end face are all intersect to the surface of the channel layer adjacent to the surface of the substrate; the first insulating layer including a third end face and a fourth end face disposed opposite to each other, the third end face and the fourth end face are all intersect to the surface of the first insulating layer covering the channel layer, the gate electrode including a fifth end face and a sixth end face disposed opposite to each other, the fifth end face and the sixth end face are all intersect to the surface of the gate electrode disposed on the first insulating layer, and the first end face, the third end face, and the fifth end face are coplanar, the second end face, the fourth end face and the sixth end face are coplanar.

wherein compared to the sixth end face, the fifth end face is disposed closer to the source electrode; compared to the fifth end face, the sixth end face is disposed closer to the drain electrode, the distance between the fifth end face and the planar of the surface of the gate electrode, the surface of the gate electrode is adjacent to the source electrode, are greater or equal to zero; and the distance between the sixth end face and the planar of the surface of the gate electrode, the surface of the gate electrode is adjacent to drain electrode are greater or equal to zero.

Compared to the conventional technology, the passivation layer of the array substrate in the present application includes HfO₂, HfO₂ has a high dielectric constant and a high transmittance. When the common electrode, the passivation layer and pixel electrode forming the storage capacitor, the facing area of the common electrode and the passivation layer is unchanged, and under the status of the thickness of the passivation layer is the same, the capacitance of the storage capacitor can be increased. When the capacitance of the storage capacitor is unchanged, and the thickness of the passivation layer is unchanged, the area of the storage capacitor is decreased, therefore, the stability of the pixel of the array substrate applied in the display panel and the aperture of the array substrate can be increased.

The present application also provide a method of manufacturing an array substrate, wherein the method of manufacturing the array substrate including:

providing a substrate;

forming a channel layer adjacent to the surface of the substrate;

forming a first insulating layer to cover the channel layer;

forming a gate electrode disposed on the first insulating layer and remote from the channel layer;

forming a second insulating layer to cover the gate electrode, forming a first through hole and a second through hole disposed spaced apart in the second insulating layer;

forming a source electrode and a drain electrode spaced apart on the second insulating layer, and the source electrode is electrically connected to the channel layer through the first through hole, the drain electrode is electrically connected to the channel layer through the second through hole;

forming a planarization layer to cover the source electrode and the drain electrode, and a third through hole is formed on the planarization layer corresponding to the drain electrode;

forming a common electrode on the planarization layer;

forming a passivation layer including HfO₂ to cover the common electrode, and a four through hole is formed on the passivation layer corresponding to the drain electrode, and the fourth through hole is communication with the third through hole; and

forming a pixel electrode on the passivation layer, disposed corresponding to the common electrode, and electrically connected to the drain electrode through the third through hole and the fourth through hole, wherein the pixel electrode, the passivation layer and the common electrode constituting a storage capacitor.

wherein the method of manufacturing an array substrate further including:

forming a buffer layer disposed on the substrate;

the step of “forming a channel layer adjacent to the surface of the substrate” including:

forming the channel layer on the surface of the buffer layer remote from the substrate.

wherein the steps of “forming a channel layer adjacent to the surface of the substrate”, “forming a first insulating layer to cover the channel layer”, “forming a gate electrode disposed on the first insulating layer and remote from the channel layer” further including:

forming an oxide semiconductor layer, a first insulating layer and a first metal layer stacked sequentially adjacent to the surface of the substrate;

forming a first photoresist layer to cover the first metal layer;

patterning the first photoresist layer to retain a first photoresist pattern disposed on the middle of the first metal layer;

using the first photoresist pattern as a mask, etching the first metal layer and first dielectric material layer not protected by the first photoresist pattern and forming the gate electrode and the first insulating layer respectively;

performing the plasma treatment to the exposed oxide semiconductor layer to form a first contact portion and a second contact portion, the oxide semiconductor layer not performed the plasma treatment is as the channel layer; and

removing the first photoresist pattern.

wherein the steps of “forming a source electrode and a drain electrode spaced apart on the second insulating layer, and the source electrode is electrically connected to the channel layer through the first through hole, the drain electrode is electrically connected to the channel layer through the second through hole” further including:

forming a second metal layer on the second insulation layer;

forming a second photoresist layer covering on the second metal layer;

removing the second photoresist layer facing to the gate electrode, and the length of the removed second photoresist layer is greater than or equal to the length of the gate electrode, the second photoresist layer formed a second photoresist pattern;

using the second photoresist pattern as a mask, etching the second metal layer not covered by the second photoresist pattern to form the source electrode and the drain electrode; and

removing the second photoresist pattern.

A liquid crystal display panel is also provided in the present application, the liquid crystal display panel include the array substrate illustrated in the embodiment described above.

### BRIEF DESCRIPTION OF THE DRAWINGS

In order to more clearly illustrate the embodiments of the present application or prior art, the following figures will be described in the embodiments are briefly introduced. It is obvious that the drawings are merely some embodiments of the present application, those of ordinary skill in this field can obtain other figures according to these figures without paying the premise.

FIG. 1 is a schematic cross-sectional structure of an array substrate according to a preferred embodiment of the present application;

FIG. 2 illustrates a schematic flow of the method of manufacturing the array substrate according to a preferred embodiment of the present application;

FIGS. 3-18 illustrate schematic structures of the array substrate corresponding to each step of the method of manufacturing the array substrate according to a preferred embodiment of the present application; and

FIG. 19 illustrates a schematic structure of a liquid crystal display panel according to a preferred embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts obtained should be considered within the scope of protection of the present application.

Specifically, the terminologies in the embodiments of the present application are merely for describing the purpose of the certain embodiment, but not to limit the invention. Examples and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

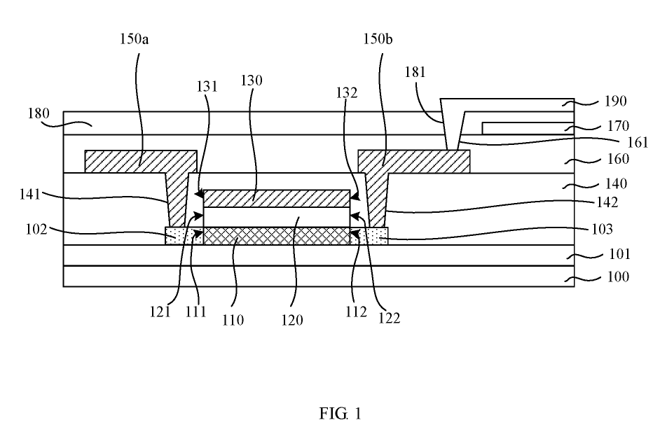

Referring to FIG. 1, FIG. 1 is a schematic cross-sectional structure of an array substrate according to a preferred embodiment of the present application. The array substrate 10 includes a substrate 100, a channel layer 110, a first insulating layer 120, a gate electrode 130, a second insulating layer 140, a source electrode 150a, a drain electrode 150b, a planarization layer 160, a common electrode 170, a passivation layer 180 and a pixel electrode 190. The channel layer 110 disposed adjacent to the surface of the substrate 100. The first insulating layer 120 covered the channel layer 110. The gate electrode 130 disposed on the surface of the first insulating layer 120 remote from the channel layer 110. The second insulating layer 140 covered the gate electrode 130, a first through hole 141 and a second through hole 142 are disposed spaced apart in the second insulating layer 140. The source electrode 150a is disposed on the second insulating layer 140, and the source electrode 150a is electrically connected to the channel layer 110 through the first through hole 141. The drain electrode 150b is disposed on the second insulating layer 140, and the drain electrode 150b is electrically connected to the channel layer 110 through the second through hole 142, and the drain electrode 150b and the source electrode 150a are disposed spaced apart. The planarization layer 160 covers the source electrode 150a and the drain electrode 150b, and the planarization layer 160 has a third through hole 161 disposed corresponding to the drain electrode 150b. The common electrode 170 is disposed on the planarization layer 160. The passivation layer 180 covers the common electrode 170, and the passivation layer 180 includes of HfO₂, the passivation layer 180 has a fourth through hole 181 corresponding to the drain electrode 150b, and the fourth through hole 181 is communication with the third through hole 161. The pixel electrode 190 is disposed on the passivation layer 180, the pixel electrode 190 is electrically connected to the drain electrode 150b through the third through hole 161 and the fourth through hole 181, and the pixel electrode 190 is disposed corresponding to the common electrode 170. The pixel electrode 190, the passivation layer 180 and the common electrode 170 constitute a storage capacitor.

Here, the gate electrode 130, the source electrode 150a and the drain electrode 150b is the gate electrode, the source electrode and the drain electrode of the thin film transistor respectively.

The material of the substrate 100 includes any one or more than one insulating material such as quartz, mica, aluminum oxide or a transparent plastic material. The substrate 110 is an insulating layer substrate to reduce the high frequency loss of the substrate 110.

The array substrate 10 further includes a buffer layer 101, the buffer layer 101 is disposed on the substrate 100. In this case, the channel layer 110 is disposed on the surface of the buffer layer 101 remote from the substrate 100. The buffer layer 101 can reduce damage to the substrate 100 during the manufacturing process of the array substrate 10.

The material of the channel layer 110 can be an oxide semiconductor material, such as, Amorphous Indium Gallium Zinc Oxide, a-IGZO.

The material of the first insulating layer 120 includes but not limited to silicon nitride (SiNx), silicon oxide (SiOx) material or etc.

The material of the gate electrode 130 includes but not limited to one or more than one metal material, such as Al, Mo, Cu, Ag, Cr, Ti, AlNi, MoTi.

The material of the second insulating layer 140 includes but not limited to silicon nitride (SiNx), silicon oxide (SiOx) material or etc.

The material of the source electrode 150a and the drain electrode 150b includes but not limited to one or more than one metal material, such as Al, Mo, Cu, Ag, Cr, Ti, AlNi, MoTi.

The material of the common electrode 170 includes a transparent conductive material, such as, the material of the common electrode 170 includes but not limited to one or more than one material of ZnO-based transparent oxide semiconductor material, SnO2-based transparent oxide based semiconductor material, In2O3-based transparent oxide semiconductor material.

The pixel electrode 190 includes a transparent conductive material, such as the material of the pixel electrode 190 includes but not limited to one or more than one material of ZnO-based transparent oxide semiconductor material, SnO2-based transparent oxide based semiconductor material, In2O3-based transparent oxide semiconductor material.

In the present embodiment, the array substrate 10 further includes a first contact portion 102 and a second contact portion 103. The first contact portion 102 and the second contact portion 103 are in contact with the channel layer 110 respectively, and the first contact portion 102 and the second contact portion 103 are disposed spaced apart. The source electrode 150a is connected to the first contact portion 102 through the first through hole 141, the first contact portion 102 is used to reduce the contact resistance between the source electrode 150a and the channel layer 110. The drain electrode 150b is connected to the second contact portion 103 through the second through hole 142, the second contact portion 103 is used to reduce the contact resistance between the drain electrode 150b and the channel layer 110. The first contact portion 102 and the second contact portion 103 can be obtained by performing a plasma treatment by the oxide semiconductor material. For example, by performing H₂ or Ar plasma treatment to an a-IGZO to form. The channel layer 110 includes a first end face 111 and a second end face 112 disposed opposite to each other. The first end face 111 and the second end face 112 are all intersect to the surface of the channel layer 110 adjacent to the surface of the substrate 100. The first insulating layer 120 includes a third end face 121 and a fourth end face 122 disposed opposite to each other. The third end face 121 and the fourth end face 122 are all intersect to the surface of the first insulating layer 120 covering the channel layer 110. The gate electrode 130 includes a fifth end face 131 and a sixth end face 132 disposed opposite to each other. The fifth end face 131 and the sixth end face 132 are all intersect to the surface the gate electrode 130 disposed on the first insulating layer 120. The first end face 111, the third end face 121, and the fifth end face 131 are coplanar, the second end face 112, the fourth end face 122 and the sixth end face 132 are coplanar.

Compared to the sixth end face 132, the fifth end face 131 is disposed closer to the source electrode 150a; compared to the fifth end face 131, the sixth end face 132 is disposed closer to the drain electrode 150b. The distance between the fifth end face 131 and the planar of the surface of the gate electrode 130, the surface of the gate electrode 130 is adjacent to the source electrode 150a, are greater or equal to zero. The distance between the sixth end face 132 and the planar of the surface of the gate electrode 130, the surface of the gate electrode 130 is adjacent to drain electrode 150b are greater or equal to zero.

Compared to the conventional technology, the passivation layer 180 of the array substrate 10 in the present application includes HfO₂, HfO₂ has a high dielectric constant and a high transmittance. When the common electrode 170, the passivation layer 180 and pixel electrode 190 forming the storage capacitor, the facing area of the common electrode 170 and the passivation layer 180 is unchanged, and under the status of the thickness of the passivation layer 180 is the same, the capacitance of the storage capacitor can be increased. When the capacitance of the storage capacitor is unchanged, and the thickness of the passivation layer 180 is unchanged, the area of the storage capacitor is decreased, therefore, the stability of the pixel of the array substrate 10 applied in the display panel and the aperture of the array substrate 10 can be increased.

Further, since comparing to the sixth end face 132, the fifth end face131 is disposed closer to the source electrode 150a and the distance between the fifth end face 131 and the planar of the surface of the gate electrode 130, the surface of the gate electrode 130 is adjacent to the source electrode 150a, are greater or equal to zero. That is, the gate electrode 130 and the source electrode 150a does not have an overlapping area, therefore, there is no parasitic capacitor between the gate 130 and the source electrode 150a. Moreover, since comparing to the fifth end face131, the sixth end face 132 is disposed closer to the drain electrode 150b, and the distance between the sixth end face 132 and the planar of the surface of the gate electrode 130, the surface of the gate electrode 130 is adjacent to drain electrode 150b are greater or equal to zero. That is, the gate electrode 130 and the drain electrode 150b does not have an overlapping area, therefore, there is no parasitic capacitor between the gate 130 and the drain electrode 150b.

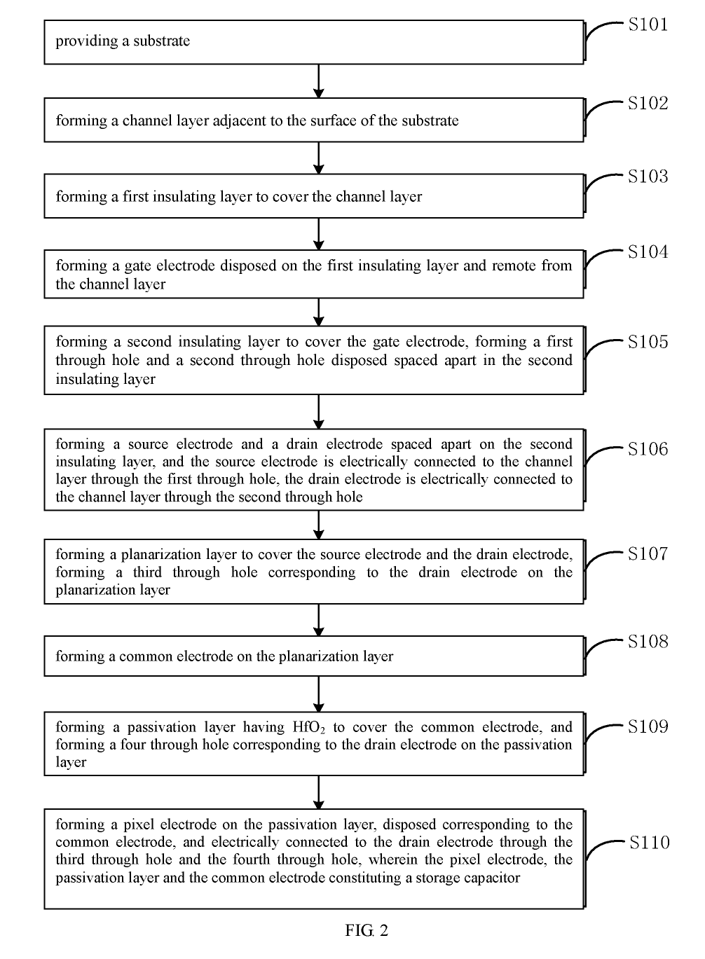

Combining to the array substrate 10 described above, following, the method of manufacturing the array substrate of the present application is described. Referring to FIG. 2, FIG. 2 illustrates a schematic flow of the method of manufacturing the array substrate according to a preferred embodiment of the present application. The method of manufacturing the array substrate includes but not limited to the following steps.

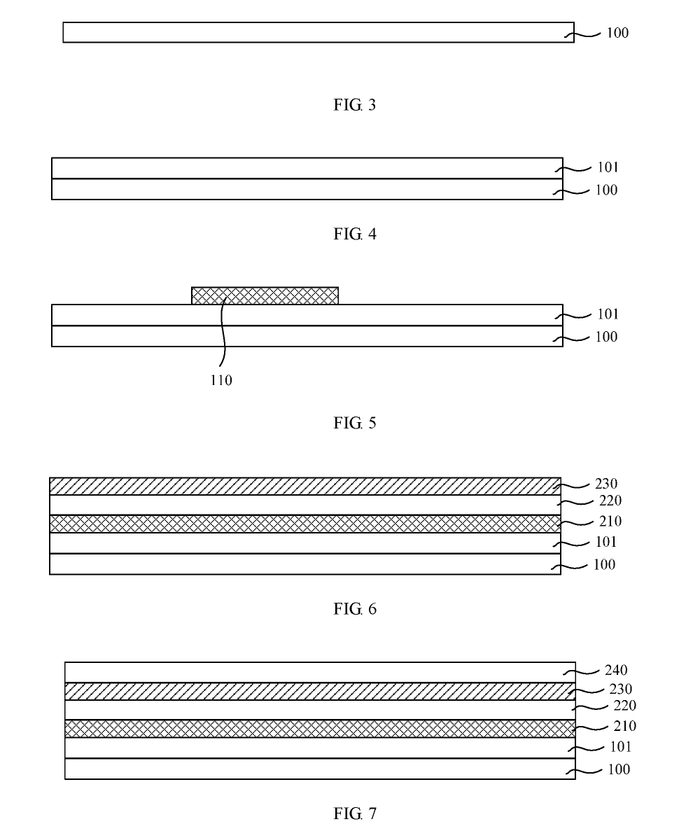

Step S101, providing a substrate 100, referring to FIG. 3.

In the present embodiment, the method of manufacturing the array substrate further including step I.

Step I, forming a buffer layer 101 disposed on the substrate 100, referring to FIG. 4.

Step S102, forming a channel layer 110 adjacent to the surface of the substrate 100. When the method of manufacturing the array substrate includes step I, the step S102 specifically includes: forming the channel layer 110 on the surface of the buffer layer 101 remote from the substrate 100, referring to FIG. 5.

Step S103, forming a first insulating layer 120 to cover the channel layer 110.

Step S104, forming a gate electrode 120 disposed on the first insulating layer 130 and remote from the channel layer 110.

In the present embodiment, the step S102, the step S103 and the step S104 can specifically include the following steps.

Step S1, an oxide semiconductor layer 210, a first insulating layer 220 and a first metal layer 230 are stacked sequentially adjacent to the surface of the substrate 100, referring to FIG. 6.

Step S2, forming a first photoresist layer 240 to cover the first metal layer 230, referring to FIG. 7.

Step S3, patterning the first photoresist layer 240 to retain a first photoresist pattern 241 disposed on the middle of the first metal layer 230, referring to FIG. 8.

Step S4, using the first photoresist pattern 241 as a mask, etching the first metal layer 230 and first dielectric material layer 220 not protected by the first photoresist pattern 241 and forming the gate electrode 130 and the first insulating layer 120 respectively, referring to FIG. 9.

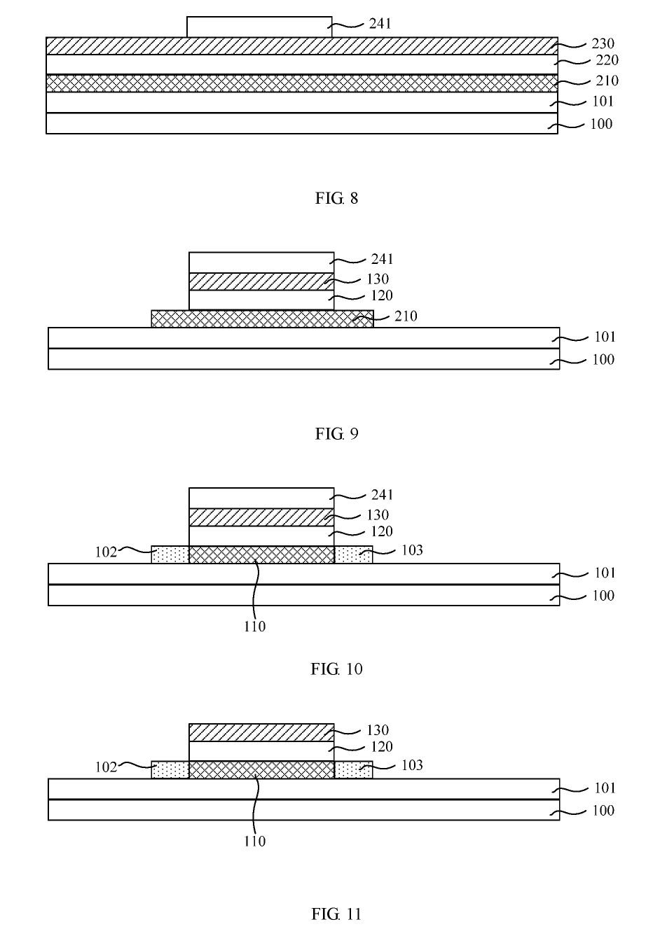

Step S5, performing the plasma treatment to the exposed oxide semiconductor layer 210 to form a first contact portion 102 and a second contact portion 103, the oxide semiconductor layer 210 not performed the plasma treatment is as the channel layer 110, referring to FIG. 10.

Compared to the conventional technology, the method of manufacturing the array substrate of the present application employed the step S1 ˜step S5, by using the first photoresist pattern 241, the gate electrode 130 and the first insulating layer 120 as masks to form the first contact portion 102, the second contact portions 103 and the channel layer 110, and there is no increase of the mask.

Step S6, removing the first photoresist pattern 241, referring to FIG. 11.

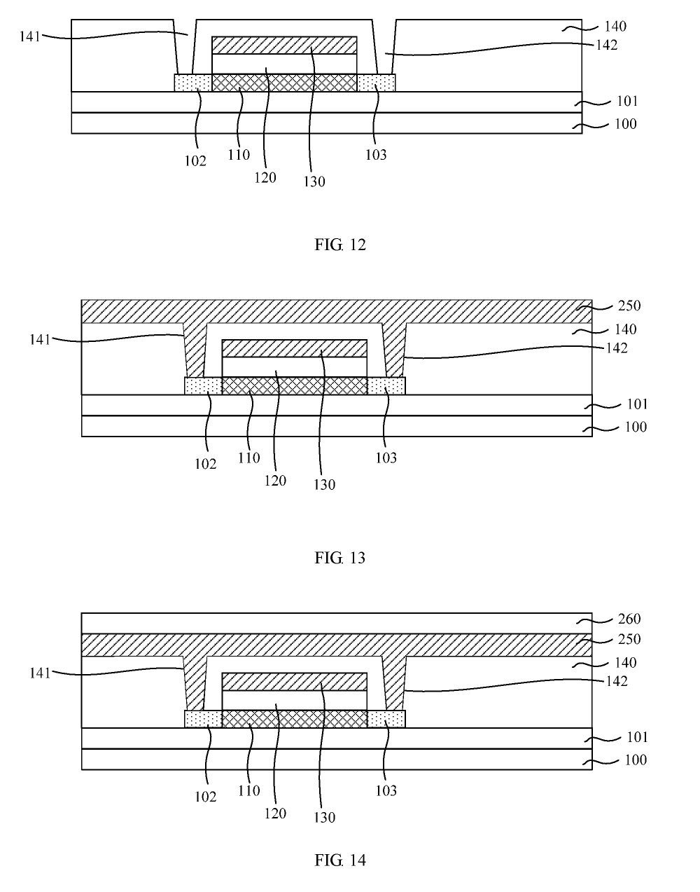

Step S105, forming a second insulating layer 140 to cover the gate electrode 130, and forming a first through hole 141 and a second through hole 142 disposed spaced apart in the second insulating layer 140, referring to FIG. 12.

Step S106, forming a source electrode 150a and a drain electrode 150b spaced apart on the second insulating layer 140, and the source electrode 150a is electrically connected to the channel layer 110 through the first through hole 141. The drain electrode 150b is electrically connected to the channel layer 110 through the second through hole 142.

Specifically, the step S106 includes the following steps.

Step S1061, forming a second metal layer 250 on the second insulation layer 140, referring to FIG. 13.

Step S1062, forming a second photoresist layer 260 covering on the second metal layer 250, referring to FIG. 14.

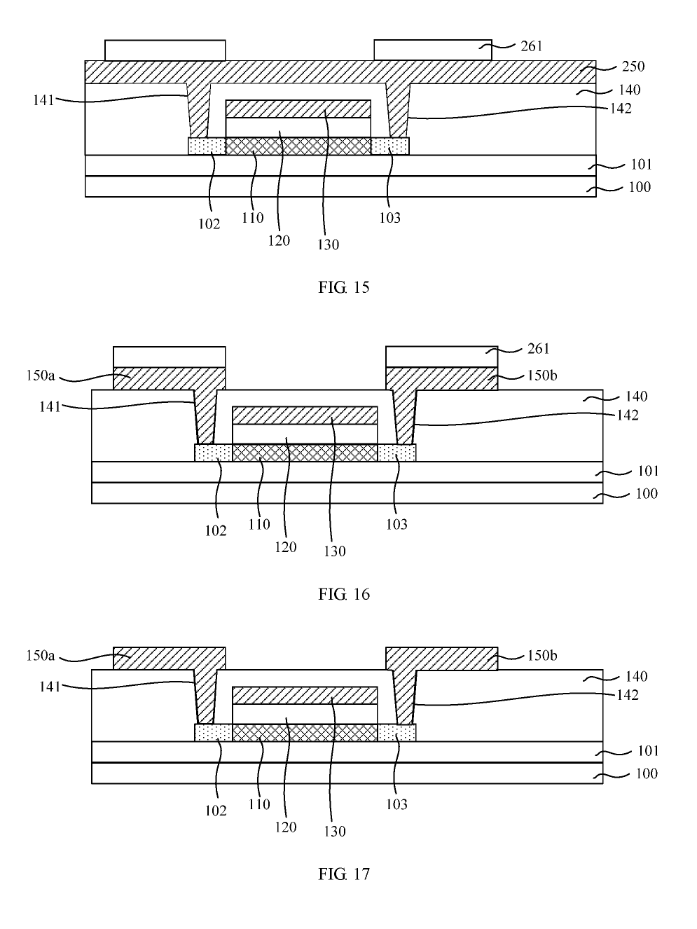

Step S1063, removing the second photoresist layer 260 facing to the gate electrode 130, and the length of the removed second photoresist layer 260 is greater than or equal to the length of the gate electrode 130, the second photoresist layer 260 formed a second photoresist pattern 261, referring to FIG. 15.

Step S1064, using the second photoresist pattern 261 as a mask, etching the second metal layer not covered by the second photoresist pattern 261 to form the source electrode 150a and the drain electrode 150b, referring to FIG. 16.

Step S1065, removing the second photoresist pattern 261, referring to FIG. 17.

Step S107, forming a planarization layer 160 to cover the source electrode 150a and the drain electrode 150b, forming a third through hole 161 corresponding to the drain electrode 150b on the planarization layer 160.

Step S108, forming a common electrode 170 on the planarization layer 160.

Step S109, forming a passivation layer 180 include HfO₂ to cover the common electrode 170, and forming a four through hole 181 corresponding to the drain electrode 150b on the passivation layer 180.

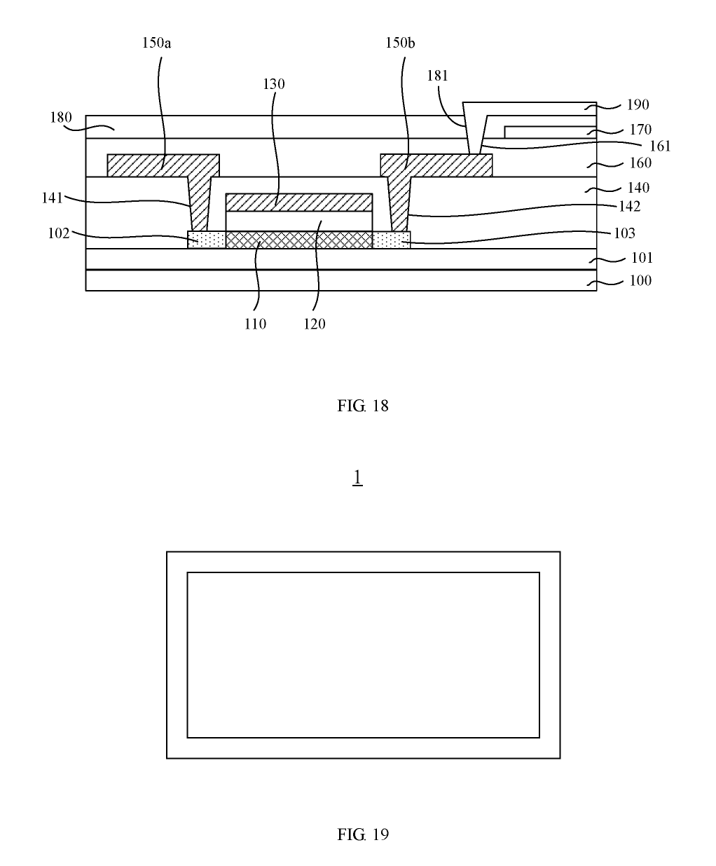

Step S110, forming a pixel electrode 190 on the passivation layer 180, disposed corresponding to the common electrode 170, and electrically connected to the drain electrode 150b through the third through hole 161 and the fourth through hole 181, the pixel electrode 190, the passivation layer 180 and the common electrode 170 constituting the storage capacitor 170, the step S107 ˜step S110 also referring to FIG. 18.

Referring to FIG. 19, FIG. 19 illustrates a schematic structure of a liquid crystal display panel according to a preferred embodiment of the present application. The liquid crystal display panel 1 includes an array substrate 10, the array substrate 10 is as described above, and not repeat them here.

Above are embodiments of the present application, which does not limit the scope of the present application. Any modifications, equivalent replacements or improvements within the spirit and principles of the embodiment described above should be covered by the protected scope of the invention.

What is claimed is:

1. An array substrate, comprising:
a substrate;
a channel layer disposed adjacent to the surface of the substrate;
a first insulating layer covered the channel layer;
a gate electrode disposed on the surface of the first insulating layer remote from the channel layer;
a second insulating layer covered the gate electrode and a first through hole and a second through hole are disposed spaced apart in the second insulating layer;
a source electrode disposed on the second insulating layer, and the source electrode electrically connected to the channel layer through the first through hole;
a drain electrode disposed on the second insulating layer, and the drain electrode is electrically connected to the channel layer through the second through hole;
a planarization layer covered the source electrode and the drain electrode, and a third through hole disposed in the planarization layer corresponding to the drain electrode;
a common electrode disposed on the planarization layer;
a passivation layer covered the common electrode, and the passivation layer comprising HfO₂, a fourth through hole disposed in the passivation layer corresponding to the drain electrode, and the fourth through hole is communication with the third through hole; and
a pixel electrode disposed on the passivation layer, the pixel electrode is electrically connected to the drain electrode through the third through hole and the fourth through hole, and the pixel electrode is disposed corresponding to the common electrode, the pixel electrode, the passivation layer and the common electrode constitute a storage capacitor.

2. The array substrate according to claim 1 further comprising:
a buffer layer disposed on the substrate; and
the channel layer is disposed on the surface of the buffer layer remote from the substrate.

3. The array substrate according to claim 1 further comprising:
a first contact portion and a second contact portion, wherein the first contact portion and the second contact portion are in contact with the channel layer respectively, and the first contact portion and the second contact portion are disposed spaced apart;
the source electrode is connected to the first contact portion through the first through hole, the first contact portion is used to reduce the contact resistance between the source electrode and the channel layer; and
the drain electrode is connected to the second contact portion through the second through hole, the second contact portion is used to reduce the contact resistance between the drain electrode and the channel layer.

4. The array substrate according to claim 3, wherein the channel layer comprising a first end face and a second end face disposed opposite to each other, the first end face and the second end face are all intersect to the surface of the channel layer adjacent to the surface of the substrate; the first insulating layer comprising a third end face and a fourth end face disposed opposite to each other, the third end face and the fourth end face are all intersect to the surface of the first insulating layer covering the channel layer, the gate electrode comprising a fifth end face and a sixth end face disposed opposite to each other, the fifth end face and the sixth end face are all intersect to the surface of the gate electrode disposed on the first insulating layer, and the first end face, the third end face, and the fifth end face are coplanar, the second end face, the fourth end face and the sixth end face are coplanar.

5. The array substrate according to claim 4, wherein compared to the sixth end face, the fifth end face is disposed closer to the source electrode; compared to the fifth end face, the sixth end face is disposed closer to the drain electrode, the distance between the fifth end face and the planar of the surface of the gate electrode, the surface of the gate electrode is adjacent to the source electrode, are greater or equal to zero; and the distance between the sixth end face and the planar of the surface of the gate electrode, the surface of the gate electrode is adjacent to drain electrode are greater or equal to zero.

6. A method of manufacturing an array substrate, wherein the method of manufacturing the array substrate comprising:
providing a substrate;
forming a channel layer adjacent to the surface of the substrate;
forming a first insulating layer to cover the channel layer;
forming a gate electrode disposed on the first insulating layer and remote from the channel layer;
forming a second insulating layer to cover the gate electrode, forming a first through hole and a second through hole disposed spaced apart in the second insulating layer;
forming a source electrode and a drain electrode spaced apart on the second insulating layer, and the source electrode is electrically connected to the channel layer through the first through hole, the drain electrode is electrically connected to the channel layer through the second through hole;
forming a planarization layer to cover the source electrode and the drain electrode, and a third through hole is formed on the planarization layer corresponding to the drain electrode;
forming a common electrode on the planarization layer;
forming a passivation layer comprising HfO₂ to cover the common electrode, and a four through hole is formed on the passivation layer corresponding to the drain electrode, and the fourth through hole is communication with the third through hole; and
forming a pixel electrode on the passivation layer, disposed corresponding to the common electrode, and electrically connected to the drain electrode through the third through hole and the fourth through hole, wherein the pixel electrode, the passivation layer and the common electrode constituting a storage capacitor.

7. The method of manufacturing an array substrate according to claim 6, wherein the method of manufacturing an array substrate further comprising:
forming a buffer layer disposed on the substrate;
the step of “forming a channel layer adjacent to the surface of the substrate” comprising forming the channel layer on the surface of the buffer layer remote from the substrate.

8. The method of manufacturing an array substrate according to claim 6, wherein the steps of “forming a channel layer adjacent to the surface of the substrate”, “forming a first insulating layer to cover the channel layer”, “forming a gate electrode disposed on the first insulating layer and remote from the channel layer” further comprising:
forming an oxide semiconductor layer, a first insulating layer and a first metal layer stacked sequentially adjacent to the surface of the substrate;
forming a first photoresist layer to cover the first metal layer;
patterning the first photoresist layer to retain a first photoresist pattern disposed on the middle of the first metal layer;
using the first photoresist pattern as a mask, etching the first metal layer and first dielectric material layer not protected by the first photoresist pattern and forming the gate electrode and the first insulating layer respectively;
performing the plasma treatment to the exposed oxide semiconductor layer to form a first contact portion and a second contact portion, the oxide semiconductor layer not performed the plasma treatment is as the channel layer; and
removing the first photoresist pattern.

9. The method of manufacturing an array substrate according to claim 6, wherein the steps of “forming a source electrode and a drain electrode spaced apart on the second insulating layer, and the source electrode is electrically connected to the channel layer through the first through hole, the drain electrode is electrically connected to the channel layer through the second through hole” further comprising:
forming a second metal layer on the second insulation layer;
forming a second photoresist layer covering on the second metal layer;
removing the second photoresist layer facing to the gate electrode, and the length of the removed second photoresist layer is greater than or equal to the length of the gate electrode, the second photoresist layer formed a second photoresist pattern;
using the second photoresist pattern as a mask, etching the second metal layer not covered by the second photoresist pattern to form the source electrode and the drain electrode; and
removing the second photoresist pattern.

10. A liquid crystal display panel, wherein the liquid crystal display panel having an array substrate, the array substrate comprising:
a substrate;
a channel layer disposed adjacent to the surface of the substrate;
a first insulating layer covered the channel layer;
a gate electrode disposed on the surface of the first insulating layer remote from the channel layer;
a second insulating layer covered the gate electrode and a first through hole and a second through hole are disposed spaced apart in the second insulating layer;
a source electrode disposed on the second insulating layer, and the source electrode electrically connected to the channel layer through the first through hole;
a drain electrode disposed on the second insulating layer, and the drain electrode is electrically connected to the channel layer through the second through hole;
a planarization layer covered the source electrode and the drain electrode, and a third through hole disposed in the planarization layer corresponding to the drain electrode;
a common electrode disposed on the planarization layer;
a passivation layer covered the common electrode, and the passivation layer comprising HfO₂, a fourth through hole disposed in the passivation layer corresponding to the drain electrode, and the fourth through hole is communication with the third through hole; and
a pixel electrode disposed on the passivation layer, the pixel electrode is electrically connected to the drain electrode through the third through hole and the fourth through hole, and the pixel electrode is disposed corresponding to the common electrode, the pixel electrode, the passivation layer and the common electrode constitute a storage capacitor.

11. The liquid crystal display panel according to claim 10, wherein the array substrate further comprising:
a buffer layer disposed on the substrate; and
the channel layer is disposed on the surface of the buffer layer remote from the substrate.

12. The liquid crystal display panel according to claim 10, wherein the array substrate further comprising:
a first contact portion and a second contact portion, wherein the first contact portion and the second contact portion are in contact with the channel layer respectively, and the first contact portion and the second contact portion are disposed spaced apart;
the source electrode is connected to the first contact portion through the first through hole, the first contact portion is used to reduce the contact resistance between the source electrode and the channel layer; and
the drain electrode is connected to the second contact portion through the second through hole, the second contact portion is used to reduce the contact resistance between the drain electrode and the channel layer.

13. The liquid crystal display panel according to claim 12, wherein the channel layer comprising a first end face and a second end face disposed opposite to each other, the first end face and the second end face are all intersect to the surface of the channel layer adjacent to the surface of the substrate; the first insulating layer comprising a third end face and a fourth end face disposed opposite to each other, the third end face and the fourth end face are all intersect to the surface of the first insulating layer covering the channel layer, the gate electrode comprising a fifth end face and a sixth end face disposed opposite to each other, the fifth end face and the sixth end face are all intersect to the surface of the gate electrode disposed on the first insulating layer, and the first end face, the third end face, and the fifth end face are coplanar, the second end face, the fourth end face and the sixth end face are coplanar.

14. The liquid crystal display panel according to claim 13, wherein compared to the sixth end face, the fifth end face is disposed closer to the source electrode; compared to the fifth end face, the sixth end face is disposed closer to the drain electrode, the distance between the fifth end face and the planar of the surface of the gate electrode, the surface of the gate electrode is adjacent to the source electrode, are greater or equal to zero; and the distance between the sixth end face and the planar of the surface of the gate electrode, the surface of the gate electrode is adjacent to drain electrode are greater or equal to zero.
